(19) United States
(12) Patent Application Publication
(10) Pub. No.: US 2024/0237387 A9
(43) Pub. Date: Jul. 11, 2024

(54) LIGHT-EMITTING APPARATUS WITH IMPROVED CHARGE TRANSPORT LAYER

(71) Applicant: SHARP KABUSHIKI KAISHA, Sakai City (JP)

(72) Inventor: ANDREA ZAMPETTI, Abingdon (GB)

(21) Appl. No.: 17/972,928

(22) Filed: Oct. 25, 2022

(51) Int. Cl. H10K 50/16; H10K 50/115; H10K 50/15

(52) U.S. Cl. CPC H01L 51/5072; H01L 51/502; H01L 51/5056; H01L 2251/5369

(57) ABSTRACT

A light-emitting apparatus having an improved charge transport layer is disclosed. The apparatus may include a substrate and a first electrode layer disposed on the substrate. The apparatus may further include an emissive layer including quantum dots soluble in a first solvent having a first polarity, where the emissive layer may be in electrical contact with the first electrode layer and the second electrode layer. The apparatus may further include a hole transport layer between the emissive layer and first electrode layer and an electron transport layer between the emissive layer and the second electrode layer. The electron transport layer may include metal-oxide nanoparticles. The metal-oxide nanoparticles may be soluble in a second solvent having a second polarity lower than the first polarity.

### FIELD

The present disclosure generally relates to light-emitting displays (e.g., quantum-dot light-emitting diode (QLED) displays and in particular relates to a light-emitting apparatus with an improved charge transport layer.

### BACKGROUND

QLEDs represent an emerging emissive display technology. More specifically, quantum dots (QDs) are nano-crystalline semiconductor materials that typically include a core-shell-ligand structure. A primary feature of such materials is the quantum confinement effect, by which the wavelength of light emitted from a quantum dot depends on its size. In addition, quantum dots may provide emitted light with an enhanced color purity and generate that light with a higher internal quantum efficiency (IQE) compared to organic semiconductors conventionally employed in organic LEDs (OLEDs). These properties have attracted widespread attention in the design of optoelectronic devices, such as light-emitting devices. However, when quantum dots (QDs) are included in an emissive layer (EML) in a QLED, the QDs typically are not achieving their maximum theoretical efficiency.

A conventional QLED may include a QD light-emitting layer sandwiched between two charge transport layers (CTLs) (e.g., a hole transport layer (HTL) and an electron transport layer (ETL)). The charge injections from the ETL to the EML and from the HTL to the EML are generally not balanced in mostly QLEDs, mainly due to poor injection into the QDs of the EML layer and a significant energy barrier height at interfaces between QDs and CTLs. Such drawbacks may result both in a charge accumulation at the QD/CTL interfaces and thus an inefficient charge balance in the EML. These factors, in turn, may contribute to current leakage across the device structure and a corresponding decrease in the efficiency of the device. The inventor participated in the QANDELA project (application number:28271) funded by Innovate UK and derived the following inventions in order to achieve the technology for Cd-free quantum dot light emitting diode and signage.

### SUMMARY

The present disclosure is directed to a light-emitting apparatus with an improved charge transport layer (CTL) (e.g., a hole transport layer (HTL) or an electron transport layer (ETL)) (e.g., to provide improved efficiency).

In accordance with a first aspect of the present disclosure, a light-emitting apparatus may include a substrate and a first electrode layer disposed on the substrate. The apparatus may also include an emissive layer including quantum dots soluble in a first solvent having a first polarity. The apparatus may also include a second electrode layer disposed opposite the emissive layer from the first electrode layer. The emissive layer may be in electrical contact with the first electrode layer and the second electrode layer. The apparatus may also include a hole transport layer between the emissive layer and first electrode layer. The apparatus may also include an electron transport layer between the emissive layer and the second electrode layer. The electron transport layer may include metal-oxide nanoparticles. The metal-oxide nanoparticles may be soluble in a second solvent having a second polarity lower than the first polarity.

In an implementation of the first aspect, the metal-oxide nanoparticles may range from 3 nm to 20 nm in size.

In another implementation of the first aspect, the metal-oxide nanoparticles may be selected from a group including Group I, Group IV, Group XII, Group XIII, and Group XIV of the periodic table.

In another implementation of the first aspect, the metal-oxide nanoparticles may be deposited from a solution process selected from a group including spin coating, spray coating, blade coating, screen printing, inkjet printing, and dispensing.

In another implementation of the first aspect, the metal-oxide nanoparticles may be equal to or smaller than the quantum dots in size.

In another implementation of the first aspect, the electron transport layer may include multiple layers of metal-oxide nanoparticles.

In another implementation of the first aspect, each of the multiple layers of metal-oxide nanoparticles may include metal-oxide nanoparticles having a corresponding size.

In another implementation of the first aspect, the multiple layers of metal-oxide nanoparticles may be deposited in order of increasing size of the metal-oxide nanoparticles.

In another implementation of the first aspect, a first metal-oxide nanoparticle layer of the multiple layers of metal-oxide nanoparticles may include metal-oxide nanoparticles equal to or smaller than the quantum dots in size.

In another implementation of the first aspect, the metal-oxide nanoparticle layers following the first metal-oxide nanoparticle layer may have a third polarity greater than the second polarity.

In another implementation of the first aspect, the electron transport layer may include a blend of metal-oxide nanoparticles including different metal groups of the periodic table.

In another implementation of the first aspect, the blend of metal-oxide nanoparticles may include metal-oxide nanoparticles of varying size.

In another implementation of the first aspect, the metal-oxide nanoparticles of varying size may include at least one type of metal-oxide nanoparticle having a size equal to or smaller than the quantum dots.

In another implementation of the first aspect, the second polarity may be less than 0.5 when stated as a normalized Dimroth-Reichardt polarity.

In another implementation of the first aspect, the electron transport layer may further include a dispersant, a stabilizer, or an additive agent to increase the chemical stability of the electron transport layer.

In another implementation of the first aspect, the at least one of a dispersant, a stabilizer, or an additive agent may include a plurality of chemical compounds having a combination of metal, semimetal, and nonmetal atoms

In another implementation of the first aspect, the at least one of a dispersant, a stabilizer, or an additive agent may include nonmetal atoms.

In another implementation of the first aspect, the at least one of a dispersant, a stabilizer, or an additive agent may include at least one insulating property.

### BRIEF DESCRIPTION OF DRAWINGS

Aspects of the example disclosure are best understood from the following detailed description when read with the accompanying figures. Various features are not drawn to scale. Dimensions of various features may be arbitrarily increased or reduced for clarity of discussion.

FIG. 1 is a cross-sectional side view of a QLED structure, in accordance with an example implementation of the present disclosure.

FIGS. 2A, 2B, and 2C are cross-sectional side views of progressive states of a QLED structure during a manufacturing process, in accordance with an example implementation of the present disclosure.

FIGS. 3A and 3B are cross-sectional views of different types of QDs, in accordance with an example implementation of the present disclosure.

FIGS. 4A and 4B are graphs of current density versus voltage and external quantum efficiency (EQE) versus current density, respectively, for a QLED structure in which an electron transport layer (ETL) dispersion including hexane is deposited on a QLED EML, in accordance with an example implementation of the present disclosure.

FIGS. 5A and 5B are graphs of current density versus voltage and EQE versus current density, respectively, for a QLED structure in which an ETL dispersion including ethanol is deposited on a QLED EML and rinsed with acetone, in accordance with an example implementation of the present disclosure.

### DESCRIPTION

The following description contains specific information pertaining to exemplary implementations in the present disclosure. The drawings and their accompanying detailed description are directed to exemplary implementations. However, the present disclosure is not limited to these exemplary implementations. Other variations and implementations of the present disclosure will occur to those skilled in the art. Unless noted otherwise, like or corresponding elements in the figures may be indicated by like or corresponding reference numerals. Moreover, the drawings and illustrations are generally not to scale and are not intended to correspond to actual relative dimensions.

For consistency and ease of understanding, like features are identified (although, in some examples, not shown) by numerals in the exemplary figures. However, the features in different implementations may be different in other respects, and therefore will not be narrowly confined to what is shown in the figures.

The phrases “in one implementation” and “in some implementations” may each refer to one or more of the same or different implementations. The term “coupled” is defined as connected, whether directly or indirectly via intervening components, and is not necessarily limited to physical connections. The term “comprising” means “including, but not necessarily limited to” and specifically indicates open-ended inclusion or membership in the described combination, group, series, and equivalent.

Additionally, any two or more of the following paragraphs, (sub-)bullets, points, actions, behaviors, terms, alternatives, examples, or claims described in the following disclosure may be combined logically, reasonably, and properly to form a specific method. Any sentence, paragraph, (sub-)bullet, point, action, behavior, term, or claim described in the following disclosure may be implemented independently and separately to form a specific method. Dependency, e.g., “according to”, “more specifically”, “preferably”, “in some implementations”, “in one implementation”, “in some embodiments”, “in one embodiment”, “in one alternative”, etc., in the following disclosure refers to just one possible example which would not restrict the specific method.

For explanation and non-limitation, specific details, such as functional entities, techniques, protocols, and standards, are set forth for providing an understanding of the described technology. In other examples, detailed description of well-known methods, technologies, systems, and architectures are omitted so as not to obscure the description with unnecessary details.

Also, while certain directional references (e.g., top, bottom, up, down, height, width, and so on) are employed in the description below and appended claims, such references are utilized to provide guidance regarding the positioning and dimensions of various elements relative to each other and are not intended to limit the orientation of the various embodiments to those explicitly discussed herein.

Embodiments disclosed herein relate to a light-emitting device and associated manufacturing methods thereof. In some implementations, the light-emitting device may include an emissive layer containing quantum dots and one or more electron transport materials or layers (e.g., stacked or blended) that include nanoparticles of different sizes. In some embodiments, components of at least a first electron transport layer (ETL) including the nanoparticles may be deposited atop a quantum-dot (emissive) layer, or EML, and may be soluble in a solvent having a solvent polarity within a predetermined range of the polarity of a solvent used with the EML. The light-emitting devices may be implemented in various display applications (e.g., high-resolution multicolor displays).

In some implementations, the LED structures described herein may improve charge injection from one or more of the charge transport materials to the light-emitting layer to achieve efficient charge balance within the emissive layer, such as by depositing electron-transporting metal-oxide nanoparticles that are soluble in a solvent having a polarity within a predetermined range of the polarity of a dispersion of the EML.

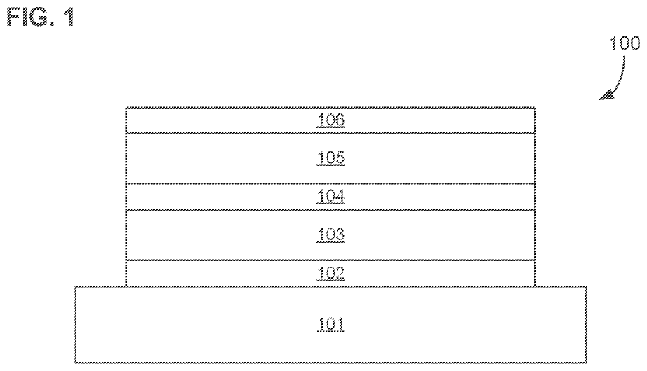

FIG. 1 is a cross-sectional side view of a light-emitting structure (QLED structure 100), in accordance with an example implementation of the present disclosure. As illustrated, QLED structure 100 may include a substrate 101, a first electrode 102, a first charge transport layer (CTL) 103, an emissive layer (EML) 104, a second CTL 105, and a second electrode 106. In some implementations, one or more additional layers may be present between an electrode 102 or 106 and EML 104, such as one or more charge injection layers (CILs), CTLs, and/or charge blocking layers (CBLs). In the present disclosure, QLED structure 100 may be a “direct” (or, in the alternative, “standard”, “normal”, or “conventional”) light-emitting structure, in which first electrode 102 (closer to substrate 101) is an anode, and any layers between the anode (first electrode 102) and EML 104 may include hole transporting layers (HTLs), hole injecting layers (HILs), and/or electron blocking layers (EBLs) layers. Accordingly, second electrode 106 (farther from substrate 101) is a cathode, and any layers between the cathode (second electrode 106) and EML 104 may include electron transporting layers (ETLs), electron injecting layers (EILs), and/or hole blocking layers (HBLs). In other implementations, QLED structure 100 may be an “inverted” light-emitting structure in which first electrode 102 is a cathode and second electrode 106 is an anode. Further, in an inverted light emitting structure, any layers between the anode (second electrode 106) and EML 104 may include HTLs, HILs, and/or EBLs, and any layers between the cathode (first electrode 102) and EML 104 may include ETLs, EILs, and/or HBLs.

In operation, when an electrical bias voltage is applied to QLED structure 100 (e.g., across first electrode 102 and second electrode 106), holes may be transported from the anode and injected into EML 104, and electrons may be conducted from the cathode and injected to EML 104. Holes and electrons may then recombine at the QDs in EML 104, thereby generating light. Some of this light may be emitted out of QLED structure 100, where it may be perceived by an external viewer, thereby providing a light-emitting device. Light may be emitted through substrate 101, in which case the device may be referred to as “bottom-emitting”, or opposite substrate 101 (e.g., via second electrode 106), in which case the device may be called “top-emitting”.

In some implementations, substrate 101 may be formed from one or more suitable materials. Examples of substrate 101 may include glass or polymer substrates. In some implementations, substrate 101 may include polyimides, polyethenes, polyethylenes, polyesters, polycarbonates, polyethersulfones, polypropylenes, and/or polyether ether ketones. Substrate 101 may be any suitable shape, size, and/or thickness that may facilitate the manufacture and operation of QLED structure 100.

Hole transport layer (HTL) 103 may include one or more layers configured to transport holes therethrough from anode 102 to EML 104. HTL 103 may be made from one or more suitable materials to facilitate its hole transport functionality. In some embodiments, HTL 103 may include one or more of poly(3,4-ethylenedioxythiophene):poly(styrenesulfonate) (PEDOT:PSS), poly(9,9-dioctylfluorene-co-N-(4-sec-butylphenyl)-diphenylamine) (TFB), poly(9-vinylcarb azole) (PVK), poly(N,N′-bis(4-butylphenyl)-N,N′-bisphenylbenzidine) (poly-TPD), metal oxide materials (e.g., V₂O₅, NiO, CuO, WO₃, and/or MoO₃), and organic small molecule materials (e.g., 2,3,5,6-tetrafluoro-7,7,8,8-tetracyanoquinodimethane (F4TCNQ), 1,4,5,8,9,11-hexaazatriphenylenehexacarbonitrile (HATCN), N4,N4′-Bis(4-(6-((3-ethyl oxetan-3-yl)methoxy)hexyl)phenyl)-N4,N4′-diphenylbiphenyl-4,4′-di amine (OTPD), N4,N4′-Bis(4-(6-((3-ethyl oxetan-3-yl)methoxy)hexyl oxy)phenyl)-N4,N4′-bis(4-methoxyphenyl)biphenyl-4,4′-diamine (QUPD), and/or N,N′-(4,4′-(Cyclohexane-1,1-diyl)bis(4,1-phenylene))bis(N-(4-(6-(2-ethyloxetan-2-yloxy)hexyl)phenyl)-3,4,5-trifluoroaniline) (X-F6-TAPC)). In embodiments where the hole transport layer 103 includes more than one layer, the material of one of the respective layers may differ from the material of one or more of the other layers. In some embodiments, HTL 103 may include more than one layer, and the material of the respective layers may be the same.

HTL 103, EML 104, and ETL 105 may be solution-processed, and thin films may be formed by any suitable method, including, but not limited to, spin coating, blade coating, inkjet printing, wire bar coating, slot die coating, gravure printing, screen printing, drop casting, or dispensing.

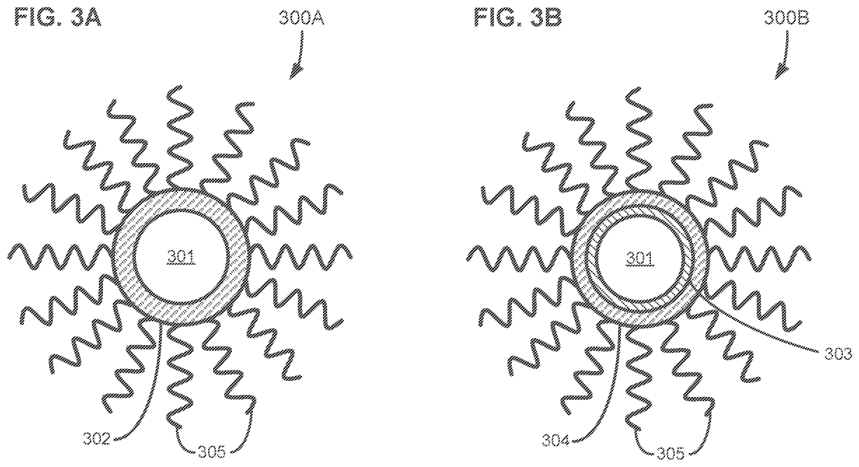

In some implementations, commercially available QDs of EML 104 may include nanoparticles (NPs) with sizes ranging from 7 to 10 nanometers (nm), depending on QD core size, shell size, and overall configuration, as described below in connection with FIGS. 3A and 3B. The emissive QD layer thickness may vary from 10 nm to 50 nm. In some implementations, the QDs of EML 104 may include 20-nm thick Cd-free QDs with core/shell size of 10 nm.

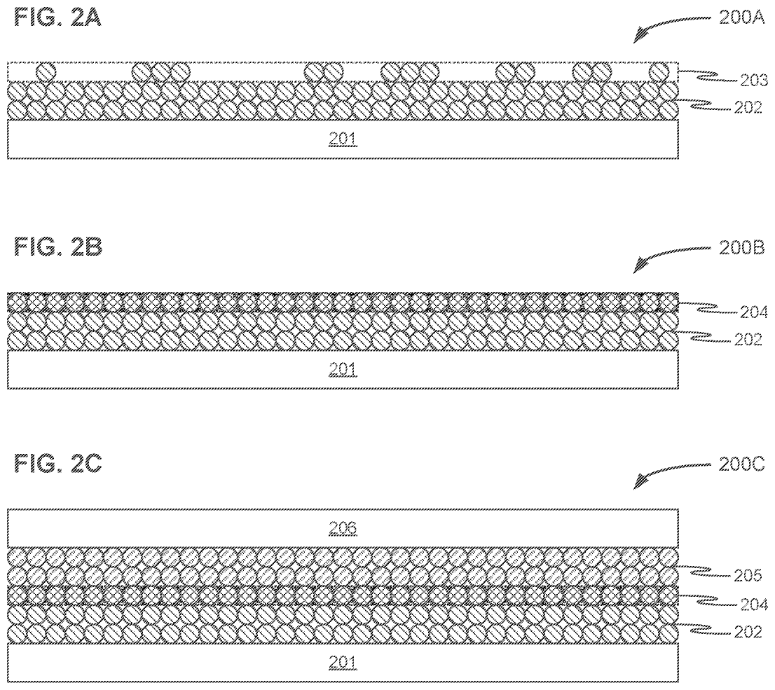

FIGS. 2A, 2B, and 2C are cross-sectional side views of progressive states of a QLED structure (e.g., QLED structure 100) during a manufacturing process, in accordance with an example implementation of the present disclosure. For example, FIG. 2A depicts a partial QLED structure 200A including anode/HTL/HIL 201, on top of which are deposited QDs 202, possibly resulting in at least some excess QDs 203 laying atop QDs 202. This feature may not be optimal, as an ETL (e.g., ETL 105 of FIG. 1) is to be deposited over QDs 202 and a homogeneous (e.g., smooth) interface therebetween is a desirable characteristic for charge balance, efficiency, and the like. In some examples, although the roughness across the surface of QDs 202 may be below 1 nm root-mean-square (RMS), excess QDs 203 may result in resulting EML (e.g., EML 104 of FIG. 1) having a “hill and valley” morphology ranging from 0 nm to approximately 5 nm.

FIG. 2B is a cross-sectional side view of a partial QLED structure 200B in which a first ETL dispersion 204 is deposited atop QDs 202 and excess QDs 203 to provide at least a portion of an ETL (e.g., ETL 105 of FIG. 1). In some implementations, if the solvent polarity of first ETL dispersion 204 is within a predetermined range of the solvent polarity of the QD dispersion for EML 104, first ETL dispersion 204 may remove excess QDs 203 by rinsing them away, as depicted in FIG. 2B, thereby improving (e.g., smoothing) the interface of EML 104 and ETL 105.

Solvents typically used for dispersing ETL nanoparticles may include linear or branched alcohols (e.g., butanol, 2-propanol, propanol, ethanol, methanol), linear or branched alkoxy alcohols (e.g., 2-methoxyethanol, 2-ethoxyethanol). Solvents used for dispersing QDs may include linear or branched alkanes (e.g., pentane, hexane, heptane, octane, nonane, decane, undecane, or dodecane).

In some implementations of the present disclosure, the solvent polarity of the solvent for first ETL dispersion 204 may refer to the polarity determined according to the method of Dimroth and Reichardt. In particular, solvent polarity values reported herein may be normalized Dimroth-Reichardt polarity parameters (e.g., solvent polarity parameters normalized to the solvent polarity value of water). In some examples, the normalized value may be more consistent with other solvent polarity scales.

Alcohols are usually highly polar solvents with values >0.5, while alkanes feature solvent values <0.1. In some implementations, the solvent is selected such that the ETL (e.g., ETL 105 of FIG. 1) may be deposited from first ETL dispersion 204 featuring a solvent with a polarity below 0.5. In some implementations, first ETL dispersion 204 may include a solvent with a solvent polarity <0.1. In some implementations, solvents for first ETL dispersion 204 may include, but are not limited to, acetone, dichloromethane, chloroform, ethyl acetate, linear or branched alkanes (e.g., pentane, hexane, heptane, octane, nonane, decane, undecane, dodecane), mono, di, and tri halogen substituted benzenes (e.g., chlorobenzene, 1,2-dibromobenzene, 1,3-dibromobenzene, 1,4-dibromobenzene, 1,3,5-tribromobenzene, 1,2,4-tribromobenzene), linear or branched ethers, and/or mono, di, and tri alkyl substituted benzenes (e.g., toluene, 1,2-dimethylbenzene, 1,3-dimethylbenzene, 1,4-dimethylbenzene).

In some embodiments, the polarity of the solvent of first ETL dispersion 204 may differ depending on the solvent used for dissolving QDs, and therefore the solvent of first ETL dispersion 204 may differ from those listed above.

In some implementations, at least first ETL dispersion 204 may include NPs equal to or smaller than 5 nm in diameter, or a blend of ETL NPs with different NP size in which at least one set of ETL NPs are smaller than 5 nm in diameter. ETL NPs that are smaller than a size of QDs 202 and excess QDs 203 (e.g., >5 nm in diameter) may allow improvement in the uniformity of the EML (e.g., EML 104 of FIG. 1) including QD 202 by passivating the region where excess QDs 203 have been rinsed.

In some embodiments, two or more consecutive ETLs may be deposited on top of QDs. For example, FIG. 2C is a cross-sectional side view of a partial QLED structure 200C in which a second ETL dispersion 205 is deposited atop first ETL dispersion 204. In some implementations, the resulting stacked ETLs may feature different NP sizes. Also, in some implementations, the order of deposition of first ETL dispersion 204 and second ETL dispersion 205 may follow an ascending order in NP size between the QDs 202 and EIL/cathode 206 (e.g., the size of NPs in first ETL dispersion 204 may be less than the size of NPs in second ETL dispersion 205). Also, in some implementations, the solvents of first ETL dispersion 204 and second ETL dispersion 205 may be different, and each solvent may have a different polarity (e.g., the polarity of the solvent for second ETL dispersion 205 may be greater than the polarity for first ETL dispersion 204). Moreover, in some implementations, more than two ETL dispersions may be employed to form the ETL.

In some implementations, NPs of ETL 105 may include metal oxides such as ZnO, MgₓZn₁₋ₓO where 0≤x≤1, AlₓZn₁₋ₓO where 0≤x≤1, GaₓZn₁₋ₓO where 0≤x≤1, LiₓZn₁₋ₓO where 0≤x≤1, SnO₂, TiO₂ and ZrO₂. In some implementations, the metal-oxide NPs may range in size (e.g., diameter) from 3 to 20 nm. In some implementations, the metal-oxide NPs may be selected from one or more of Group I, Group IV, Group XII, Group XIII, and/or Group XIV of the periodic table.

In some implementations, at least one of ETL dispersions 204 and 205 may further include a dispersant, stabilizer, or additive agent to increase the chemical stability of the formulation. These compounds may include one or more chemical compounds having a structure comprising a combination of metal, semimetal, and/or nonmetal atoms. For example, in some implementations, the dispersant, stabilizer, or additive agent may include nonmetal atoms, such as carbon, oxygen, nitrogen, and/or hydrogen atoms. In some implementations, the dispersant, stabilizer, or additive agent may include nonmetal atoms that possess at least one insulating property. In some implementations, in addition to (or instead of) a dispersant, stabilizer, or additive agent, a method of physical dispersion of nanoparticles may be applied, including, but not limited to, ultrasonic irradiation and mechanical milling. In some implementations, a total concentration NPs in the solution may range from 0.1 to 20 percent by weight (wt %).

In some implementations, ETL NPs may be thermally treated with temperatures ranging from 60° C. to 210° C. after deposition. In other implementations, ETL NPs may not be thermally treated after deposition. In some implementations, ETL NPs may be vacuum-dried at different temperatures starting from room temperature (e.g., approximately 20° C.) up to 210° C. An annealing length of time for the ETL NPs, in some implementations, may vary from 30 seconds up to 12 hours.

As a result of at least some implementations, as described above, the electrical behavior of QLED structure 100 may be improved by reducing voltage loss across EML 104 and ETL 105, thus possibly decreasing the driving voltages for QLED structure 100. Moreover, in some implementations, QLED structure 100 may feature enhanced charge balance into EML 104 as a result of ETL 105 passivation, small ETL NPs 5 nm), and/or multiple stacked or blended ETLs (e.g., by way of first ETL dispersion 204 and second ETL dispersion 205). Also, in some implementations, QLED structure 100 possessing such an enhanced charge balance may exhibit reduced charge accumulation across QLED structure 100 as a result, thereby potentially increasing the lifetime of QLED structure 100.

FIGS. 3A and 3B are cross-sectional views of two different types of quantum dots (QDs), in accordance with an example implementation of the present disclosure. In FIG. 3A, QD 300A may include a core 301, a shell 302 substantially covering core 301, and ligands 305 surrounding shell 302. In FIG. 3B, QD 300B may include core 301, an inner shell 303 substantially covering core 301, an outer shell 304 substantially covering inner shell 303, and ligands 305 surrounding outer shell 304. In other implementations, more than two shells may cover core 301. While the present disclosure focuses on the use of core-shell QDs 300A and 300B, in some implementations, the QDs may be non-core-shell type QDs that employ one or more of the same materials described below in conjunction with core-shell QDs 300A and 300B.

The cross-sections in FIGS. 3A and 3B depict QDs 300A and 300B as spherical. However, in some implementations, QDs 300A and 300B may exhibit an elongated shape (e.g., rod-like, platelet-like, or discoidal) or shapes of higher complexity (e.g., a quasi-spherical core with a multi-branched shell). Furthermore, the materials of shells 303, 303, and/or 304 may not cover core 301 evenly, and the thickness of shells 303, 303, and/or 304 may not be uniform (e.g., with a corresponding shell volume lower than, equal to, or higher than the core volume).

Examples of core 301 and shells 302, 303, and 304 may include one or more of: InP, CdSe, CdS, CdSeₓS₁₋ₓ, CdTe, CdₓZn₁₋ₓSe, CdₓZn₁₋ₓSe_{y}S_{1-y}, ZnSe, ZnS, ZnSTe, ZnSeTe, perovskites of the form ABX₃, Zn_{w}Cu_{z}In_{1-(w+z)}S, and carbon, where 0≤w, x, y, z≤1 and (w+z)≤1.

In some implementations, ligands 305 may passivate crystal defects in QD 300A and 300B and may provide for improved solubility in some solvents, as well as transport electrical charge from CTLs 103 and 105 to EML 104. In some implementations, ligands 305 may include long chain organic ligands, short chain organic ligands, inorganic molecular ligands and/or inorganic ion ligands.

In some implementations, shell 302 or outer shell 304 may be bonded with electron transport ligands 305. Such electron transport ligands 305 may have electron conducting properties to improve the injection of electrons from ETL 105 to the surface of QD 300A or 300B. In some implementations, ligands 305 may include alkyl, alkenyl, alkynyl or aryl (e.g., linear, branched or cyclic), carboxylic acids, unsaturated and saturated acids, such as octainoic acids, dodecanoic acids, oleic acids, and the like. Other implementations of electron transport ligands 305 may include compounds such as phosphate, phosphinite, or a thiolate group. Inorganic molecular electron transport ligands 305 may include metal-organic complexes and the like. Inorganic ion electron transport ligands 305 may include transition metals (e.g., Zn⁺), and the like.

In some implementations, shell 302 or outer shell 304 may be bonded with hole transport ligands 305. These hole transport ligands 305 may have hole conducting features to efficiently transport positive charge carriers from HTL 103 to the surface QD 300A or 300B. In some implementations, hole transport ligands 305 may include alkyl, alicyclic, aromatic, tertiary, ethylene (linear or branched) amines with 1 to 20 atoms of carbon; mono-valent (or di- or tri-valent) alkyl, -alkenyl, -alkynyl or aryl (linear, branched or cyclic) phosphine or phosphine oxides with 1 to 60 atoms of carbon; alkyl, -alkenyl, -alkynyl or aryl (linear, branched or cyclic) thiols with 1 to 30 atoms of carbon; and the like. Inorganic molecular hole transport ligands 305 may include metal-organic complexes and the like. Inorganic ion hole transport ligands 305 may include halides (e.g., I⁻, Br⁻ and Cl⁻), chalcogenides (e.g., S⁻, Se⁻, Te⁻), or thiocyanate (SCN⁻).

In some implementations, solvents for QDs 300A and 300B may include, but are not limited to, acetone, dichloromethane, chloroform, ethyl acetate, linear or branched alkanes (e.g., pentane, hexane, heptane, octane, nonane, decane, undecane, dodecane), linear or branched alcohols (e.g., butanol, 2-propanol, propanol, ethanol, methanol), linear or branched alkoxy alcohols (e.g., 2-methoxyethanol, 2-ethoxyethanol), mono, di, and tri halogen substituted benzenes (e.g., chlorobenzene, 1,2-dibromobenzene, 1,3-dibromobenzene, 1,4-dibromobenzene, 1,3,5-tribromobenzene, 1,2,4-tribromobenzene), linear or branched ethers, and/or mono, di, and tri alkyl substituted benzenes (e.g., toluene, 1,2-dimethylbenzene, 1,3-dimethylbenzene, 1,4-dimethylbenzene). In some implementations, the total concentration of QDs 300A and 300B in the solution may range from 0.1 to 20 wt %.

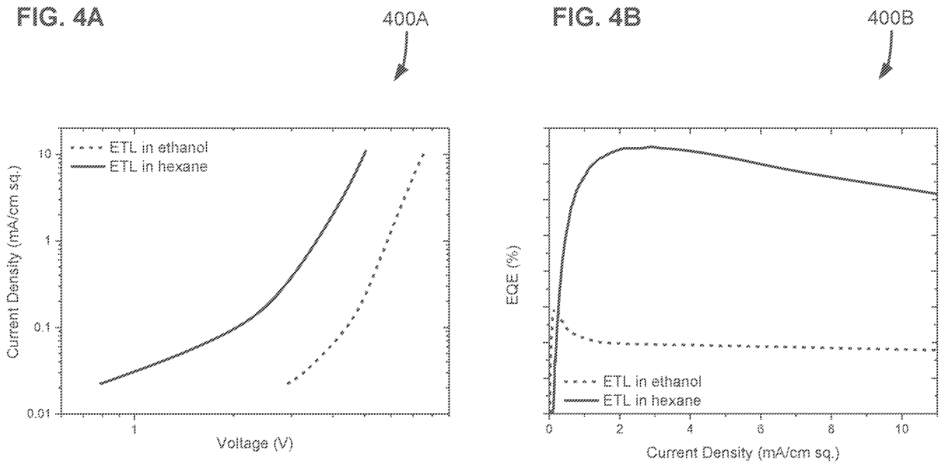

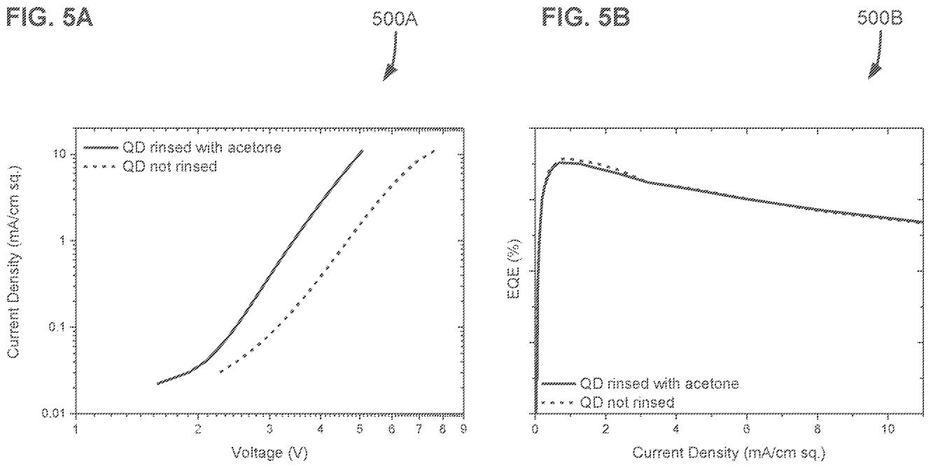

In the following discussion, two separate examples of QLED structure 100 employing embodiments of the present disclosure are described, one example in conjunction with FIGS. 4A and 4B, and another in connection with FIGS. 5A and 5B.

FIGS. 4A and 4B are graphs of current density versus voltage and external quantum efficiency (EQE) versus current density, respectively, for a QLED structure in which an ETL dispersion including hexane is deposited on a QLED EML, in accordance with an example implementation of the present disclosure. In the present example, two types of QLED structures 100 are fabricated at the same time with the same structure of glass (for substrate 101), ITO (for first conductor 102 (e.g., anode)), PEDOT:PSS/poly-TPD (for HTL 103), Cd-free QD (for EML 104), ETL 105, and aluminum (Al) (for second conductor 106 (e.g., cathode)). In some implementations, all layers of the two QLED structures 100 have been deposited by solution-processed techniques over substrate 101, except for the ITO anode (first conductor 102) and Al cathode (second conductor 106). In the present example, 20-nm-thick Cd-free QDs (e.g., with core/shell size of approximately 10 nm) have been deposited from octane dispersion. Further, a first type of QLED structure 100 uses an ETL dispersion of NPs less than 10 nm in size (e.g., in diameter) in ethanol, and a second type of QLED structure 100 uses a different ETL dispersion of NPs less than 10 nm in size in hexane. Hexane is an alkaline solvent with a solvent polarity similar to that of octane, whereas ethanol is an alcohol with a higher solvent polarity than that of octane.

FIG. 4A is a current density versus voltage graph 400A indicating that the driving voltages for QLED structure 100 employing the ETL dispersion with hexane possess a decreased driving voltage of approximately 2 V at 10 mA/cm² relative to QLED structure 100 employing the ETL dispersion with ethanol. FIG. 4B is an EQE versus current density graph 400B that indicates QLED structure 100 with ETL 105 deposited from a hexane dispersion exhibits a threefold higher EQE than that observed in QLED structure 100 with ETL 105 deposited from an ethanol solvent. With reference to FIG. 4B, a small EQE leakage may be observed at low voltages, which may be due to QD passivation after ETL deposition. In other implementations, when the same less-than-10-nm ETL NPs in hexane, as indicated above, are deposited in a solvent with a polarity similar to that of ethanol, the resulting QLED structure 100 may exhibit similar electrical and optoelectronic behavior to those observed in QLED structure 100 with less-than-10-nm ETL NPs deposited from ethanol dispersion.

FIGS. 5A and 5B are graphs of current density versus voltage and EQE versus current density, respectively, for a QLED structure in which an ETL dispersion including ethanol is deposited on EML 104 of QLED structure 100 and rinsed with acetone, in accordance with an example implementation of the present disclosure. As in the example of FIGS. 4A and 4B, two types of QLED structures 100 are fabricated at the same time with the same structure of glass (for substrate 101), ITO (for first conductor 102 (e.g., cathode)), PEDOT:PSS/poly-TPD (for HTL 103), Cd-free QD (for EML 104), ETL 105, and aluminum (Al) (for second conductor 106 (e.g., cathode)). In some implementations, all layers of the two QLED structures 100 have been deposited by solution-processed techniques over substrate 101, except for the ITO anode (first conductor 102) and Al cathode (second conductor 106). In the present example, 20-nm-thick Cd-free QDs (e.g., with core/shell size of approximately 10 nm) have been deposited from octane dispersion. Further, both a first type and a second type of QLED structure 100 uses an ETL dispersion of less-than-10-nm NPs in ethanol. To investigate a solvent with a solvent polarity halfway between the alkanes and the alcohols, in the second type of QLED structure 100, acetone has been deposited directly on top of the previously deposited QDs prior to the deposition of the ETL dispersion in ethanol to emulate an ETL deposition in acetone. Such rinsing was not applied in the first type of QLED structure 100.

FIG. 5A is a current density versus voltage graph 500A that indicates the driving voltages for the second type of QLED structure 100 have been decreased by approximately 2 V at 10 mA/cm² by rinsing the QDs with acetone relative to the first type of QLED structure 100. Further, FIG. 5B is an EQE versus current density graph 500B that indicates the second type of QLED structure 100 with QDs that are rinsed with acetone do not exhibit significant variation in EQE compared to that of the first type of QLED structure 100 that did not employ rinsing with acetone. Consequently, this acetone rinsing may demonstrate that employing a solvent with a polarity similar to acetone may be suitable for ETL deposition.

Embodiments of the present disclosure may be applicable to many display devices to permit display devices exhibiting high emission efficiency, which may be exploited to at least extend display lifetime. Examples of such devices may include televisions, mobile phones, personal digital assistants (PDAs), tablet computers, laptop computers, desktop monitors, digital cameras, and like devices for which a high-resolution display is desirable.

From the above discussion, it is evident that various techniques can be utilized for implementing the concepts of the present disclosure without departing from the scope of those concepts. Moreover, while the concepts have been described with specific reference to certain implementations, a person of ordinary skill in the art would recognize that changes can be made in form and detail without departing from the scope of those concepts. As such, the disclosure is to be considered in all respects as illustrative and not restrictive. It should also be understood that the present disclosure is not limited to the particular described implementations, but that many rearrangements, modifications, and substitutions are possible without departing from the scope of the present disclosure.

What is claimed is:

1. A light-emitting apparatus having an improved charge transport layer, the light-emitting apparatus comprising:
a substrate;
a first electrode layer disposed on the substrate;
an emissive layer including quantum dots soluble in a first solvent having a first polarity;
a second electrode layer disposed opposite the emissive layer from the first electrode layer, the emissive layer in electrical contact with the first electrode layer and the second electrode layer;
a hole transport layer between the emissive layer and first electrode layer; and
an electron transport layer between the emissive layer and the second electrode layer, the electron transport layer comprising metal-oxide nanoparticles, the metal-oxide nanoparticles being soluble in a second solvent having a second polarity lower than the first polarity.

2. The light-emitting apparatus of claim 1, wherein the metal-oxide nanoparticles range from 3 nm to 20 nm in size.

3. The light-emitting apparatus of claim 1, wherein the metal-oxide nanoparticles are selected from the group consisting of Group I, Group IV, Group XII, Group XIII, and Group XIV of the periodic table.

4. The light-emitting apparatus of claim 1, wherein the metal-oxide nanoparticles are deposited from a solution process selected from the group consisting of spin coating, spray coating, blade coating, screen printing, inkjet printing, and dispensing.

5. The light-emitting apparatus of claim 1, wherein the metal-oxide nanoparticles are equal to or smaller than the quantum dots in size.

6. The light-emitting apparatus of claim 1, wherein the electron transport layer comprises multiple layers of metal-oxide nanoparticles.

7. The light-emitting apparatus of claim 6, wherein each of the multiple layers of metal-oxide nanoparticles comprise metal-oxide nanoparticles having a corresponding size.

8. The light-emitting apparatus of claim 7, wherein the multiple layers of metal-oxide nanoparticles are deposited in order of increasing size of the metal-oxide nanoparticles.

9. The light-emitting apparatus of claim 7, wherein a first metal-oxide nanoparticle layer of the multiple layers of metal-oxide nanoparticles comprises metal-oxide nanoparticles equal to or smaller than the quantum dots in size.

10. The light-emitting apparatus of claim 9, wherein the metal-oxide nanoparticle layers following the first metal-oxide nanoparticle layer have a third polarity greater than the second polarity.

11. The light-emitting apparatus of claim 1, wherein the electron transport layer comprises a blend of metal-oxide nanoparticles comprising different metal groups of the periodic table.

12. The light-emitting apparatus of claim 11, wherein the blend of metal-oxide nanoparticles comprises metal-oxide nanoparticles of varying size.

13. The light-emitting apparatus of claim 12, wherein the metal-oxide nanoparticles of varying size include at least one type of metal-oxide nanoparticle having a size equal to or smaller than the quantum dots.

14. The light-emitting apparatus of claim 1, wherein the second polarity is less than 0.5 when stated as a normalized Dimroth-Reichardt polarity.

15. The light-emitting apparatus of claim 1, wherein the electron transport layer further comprises at least one of a dispersant, a stabilizer, or an additive agent to increase a chemical stability of the electron transport layer.

16. The light-emitting apparatus of claim 15, wherein the at least one of a dispersant, a stabilizer, or an additive agent comprises a plurality of chemical compounds having a combination of metal, semimetal, and nonmetal atoms.

17. The light-emitting apparatus of claim 15, wherein the at least one of a dispersant, a stabilizer, or an additive agent comprises nonmetal atoms.

18. The light-emitting apparatus of claim 15, wherein the at least one of a dispersant, a stabilizer, or an additive agent comprises at least one insulating property.
